(19) United States
(12) Patent Application Publication
(10) Pub. No.: US 2009/0237036 A1
(43) Pub. Date: Sep. 24, 2009

(54) FREQUENCY SYNTHESIZER AND LOOP FILTER USED THEREIN

(75) Inventors: Takeshi Ikeda, Tokyo (JP); Hiroshi Miyagi, Kanagawa (JP)

Correspondence Address: CONNOLLY BOVE LODGE & HUTZ LLP, 1875 EYE STREET, N.W., SUITE 1100, WASHINGTON, DC, 20006, US

(73) Assignee: RICOH CO., LTD., TOKYO (JP)

(21) Appl. No.: 12/375,803

(22) PCT Filed: Mar. 23, 2007
(86) PCT No.: PCT/JP2007/057014

§ 371 Date: Jan. 30, 2009

(51) Int. Cl. H02J 7/00; H03B 21/00; H03B 19/00

(52) U.S. Cl. 320/166; 327/105; 327/117

(57) ABSTRACT

An LPF (15) includes a plurality of capacitors (C₁) to (Cₙ) connected in parallel, switches (SW₁₁) to (SW₁ₙ) and (SW₂₁) to (SW₂ₙ) for carrying out switching to perform their charging/discharging operation as a pipeline processing, and a capacitor (C_{H}) connected to an output side of a parallel circuit having the capacitors (C₁) to (Cₙ), and electric charges stored sequentially in the capacitors (C₁) to (Cₙ) are obtained as an output of the parallel circuit and are sequentially stored in the capacitor (C_{H}). Consequently, it is possible to implement a great time constant as the whole circuit even if the time constant is reduced with a decrease in capacitance values of the capacitors (C₁) to (Cₙ) and (C_{H}).

### TECHNICAL FIELD

The present invention relates to a frequency synthesizer and a loop filter using the same, and more particularly to a frequency synthesizer including a charge pump circuit and a loop filter.

### BACKGROUND ART

In a wireless communicating apparatus such as a radio receiver, a television broadcast receiver or a portable telephone, generally, a frequency synthesizer using a PLL (Phase Locked Loop) is utilized as a local oscillating circuit. FIG. 1 is a diagram showing a general structure of the frequency synthesizer using the PLL. As shown in FIG. 1, the frequency synthesizer includes a crystal oscillator 1, a reference frequency divider 2, a phase comparator 3, a charge pump circuit 4, a loop filter (LPF) 5, a voltage controlled oscillator (VCO) 6 and a variable frequency divider 7.

The crystal oscillator 1 generates a signal having a predetermined frequency. The reference frequency divider 2 divides a frequency of the signal output from the crystal oscillator 1 at a fixed dividing ratio and thus generates a reference signal having a reference frequency. The phase comparator 3 detects a phase difference between the reference signal output from the reference frequency divider 2 and a comparison signal output from the variable frequency divider 7 and outputs an error signal from Up and Down terminals corresponding to the result.

When the phase of the comparison signal is lagged from that of the reference signal, the phase comparator 3 outputs, from the Up terminal, an error signal having a pulse width corresponding to the phase difference. When the phase of the comparison signal is led from that of the reference signal, the phase comparator 3 outputs, from the Down terminal, an error signal having a pulse width corresponding to the phase difference. When the phase of the comparison signal is synchronized with that of the reference signal, the error signal is not output but a so-called floating state (a high impedance state) is brought.

The charge pump circuit 4 carries out a charging or discharging operation of a capacitor constituting the LPF 5 based on the error signal output from the Up terminal or the Down terminal of the phase comparator 3. Consequently, a signal which is proportional to the phase difference detected by the phase comparator 3 is output from the LPF 5. The error signal output from the phase comparator 3 is pulse-shaped and the LPF 5 serves to remove an AC component from the same signal to set a control voltage of the VCO 6.

The VCO 6 is oscillated at a frequency which is proportional to a voltage of the signal output from the LPF 5, and generates a local oscillating signal and outputs the local oscillating signal to an outside of the frequency synthesizer and the variable frequency divider 7. The variable frequency divider 7 divides an output frequency of the VCO 4 at a specified dividing ratio and outputs the result as a comparison signal to the phase comparator 3. The frequency synthesizer thus constituted is operated in such a manner that a frequency of the comparison signal gradually approximates to that of the reference signal through a negative feedback loop even if the frequency of the comparison signal is higher or lower than that of the reference signal. Consequently, the oscillating frequency of the VCO 6 is locked into a constant frequency.

In the frequency synthesizer having the structure described above, a time constant of the LPF 5 is determined by values of the capacitor and a resistor which are included in the LPF 5. In order to increase the time constant, thereby carrying out a stable operation of the LPF 5, it is necessary to increase a capacitance value of the capacitor or the value of the resistor. When the capacitance value of the capacitor is increased, however, it is hard to integrate the LPF 5 into a semiconductor chip. For this reason, there is a problem in that it is necessary to constitute the LPF 5 as an external component of the semiconductor chip.

On the other hand, when the capacitance value of the capacitor is decreased to easily carry out an integration, it is necessary to increase a resistance value in order to increase the time constant of the LPF 5. When the resistance value is increased, however, there is a problem, in that a bad influence is exerted, for example, a thermal noise is generated so that C/N of VCO is deteriorated or a level of a spuriousness caused by a leakage of a reference frequency component is raised.

On the other hand, there has conventionally been proposed a PLL circuit which is suitable for an integration using a small integral capacitance and can improve a spurious suppression performance, thereby bringing out a performance of a digital oscillator sufficiently (for example, see Patent Document 1).

Patent Document 1: Japanese Laid-Open Patent Publication No. 11-150735

In the technique described in the Patent Document 1, an output of a phase comparator is divided into two paths and a frequency control of a VCO is carried out through a gain control circuit for one of them and an LPF for the other. A gain of a gain control circuit and a time constant of the LPF are switched depending on a state of a signal to be processed. The time constant is switched by fixing a capacitance of a capacitor to be small and controlling a transconductance of a gm amplifier constituting an integrator.

### DISCLOSURE OF THE INVENTION

In the technique described in the Patent Document 1, however, the time constant of the LPF is simply switched to be decreased or increased depending on a synchronizing state of the PLL circuit. For this reason, a fundamental solution cannot be obtained. More specifically, there is a problem in that a C/N characteristic or a spurious characteristic cannot be improved when the capacitance value of the capacitor is decreased to reduce the time constant of the LPF.

In order to solve the problem, it is an object of the present invention to enable an integration of a loop filter to be easily carried out with a decrease in a capacitance value of a capacitor and an improvement in a C/N characteristic and a spurious characteristic irrespective of a synchronizing state of a frequency synthesizer.

In order to attain the object, in the present invention, a loop filter is constituted by a plurality of capacitors connected in parallel, a switch for carrying out switching to perform a charging or discharging operation of the capacitors as a pipeline processing, and a capacitor connected between an output of a parallel circuit including the capacitors and a ground.

According to the present invention having the structure described above, the charging or discharging operation is carried out on a pipeline basis for each of the capacitors which are connected in parallel. More specifically, when the charging operation for one of the capacitors is ended, the charging operation is carried out for the next capacitor and is then carried out for the subsequent capacitor. Consequently, results charged respectively are sequentially stored in the capacitors connected to an output of a parallel circuit. Thus, it is possible to equivalently implement a great time constant as a whole through a group of the capacitors even if the time constant of each of the capacitors is reduced with a decrease in the capacitance values of the capacitors connected in parallel. Accordingly, it is possible to decrease the capacitance value of the capacitor, thereby carrying out the integration easily. In addition, it is possible to improve the C/N characteristic and the spurious characteristic irrespective of the synchronizing state of the frequency synthesizer.

### BRIEF DESCRIPTION OF THE DRAWINGS

FIG. 1 is a diagram showing a general structure of a frequency synthesizer using a PLL,

FIG. 2 is a diagram showing an example of a structure of a frequency synthesizer according to the present embodiment,

FIG. 3 is a diagram showing an example of a structure of a charge pump circuit according to the present embodiment,

FIG. 4 is a diagram showing an example of a structure of a loop filter according to the present embodiment, and

FIG. 5 is a diagram showing an example of a clock signal generated by a clock generator according to the present embodiment.

### BEST MODE FOR CARRYING OUT THE INVENTION

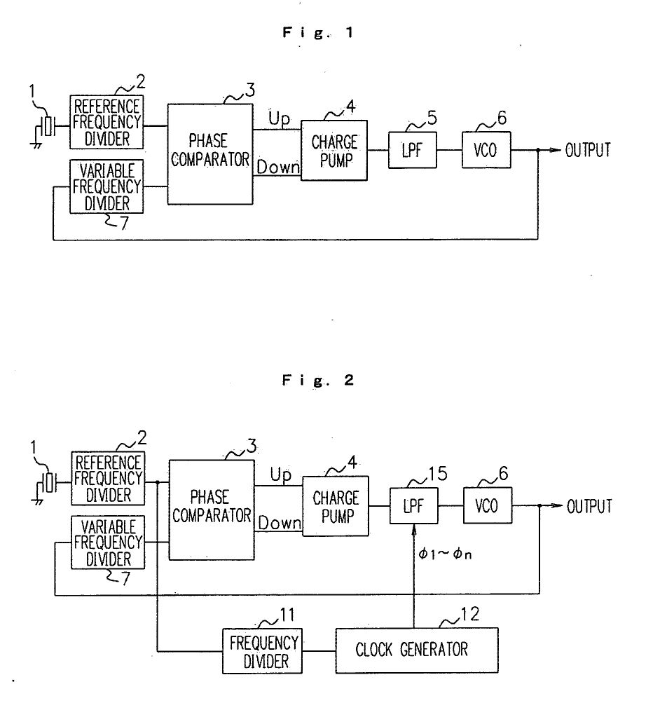

An embodiment according to the present invention will be described below with reference to the drawings. FIG. 2 is a diagram showing an example of a structure of a frequency synthesizer according to the present embodiment. In FIG. 2, components having the same functions as those of the components shown in FIG. 1 have the same reference numerals. As shown in FIG. 2, a frequency synthesizer according to the present embodiment includes a crystal oscillator 1, a reference frequency divider 2, a phase comparator 3, a charge pump circuit 4, a loop filter (LPF) 15, a voltage controlled oscillator (VCO) 6, a variable frequency divider 7, a frequency divider 11 and a clock generator 12.

The crystal oscillator 1 generates a signal having a predetermined frequency. The reference frequency divider 2 divides a frequency of the signal output from the crystal oscillator 1 at a fixed dividing ratio and thus generates a reference signal having a reference frequency. A reference generator according to the present invention is constituted by the crystal oscillator 1 and the reference frequency divider 2. The phase comparator 3 detects a phase difference between the reference signal output from the reference frequency divider 2 and a comparison signal output from the variable frequency divider 7 and outputs an error signal from Up and Down terminals corresponding to the result.

When the phase of the comparison signal is lagged from that of the reference signal, the phase comparator 3 outputs, from the Up terminal, an error signal having a pulse width corresponding to the phase difference. When the phase of the comparison signal is led from that of the reference signal, the phase comparator 3 outputs, from the Down terminal, an error signal having a pulse width corresponding to the phase difference. When the phase of the comparison signal is synchronized with that of the reference signal, the error signal is not output but a so-called floating state (a high impedance state) is brought.

The charge pump circuit 4 carries out a charging or discharging operation of a capacitor constituting the LPF 15 based on the error signal output from the Up terminal or the Down terminal of the phase comparator 3. FIG. 3 is a diagram showing an example of a structure of the charge pump circuit 4. The charge pump circuit 4 includes a first switch 4a connected to a power supply and a second switch 4b connected to a ground, and either of the first and second switches 4a and 4b is turned ON depending on a phase lead/lag of the comparison signal with respect to the reference signal.

More specifically, in the charge pump circuit 4, when the phase of the comparison signal is lagged from that of the reference signal, the first switch 4a is turned ON in response to the error signal supplied from the Up terminal of the phase comparator 3 so that an electric charge is supplied to (stored in) the capacitor of the LPF 15. On the other hand, when the phase of the comparison signal is led from that of the reference signal, the second switch 4b is turned ON in response to the error signal supplied from the Down terminal of the phase comparator 3 so that the electric charge stored in the capacitor of the LPF 15 is discharged (pumped).

The LPF 15 serves to remove an AC component from the error signal output from the phase comparator 3 and passing through the charge pump circuit 4. More specifically, the error signal output from the phase comparator 3 is pulse-shaped and the LPF 15 serves to remove the AC component from the same signal to set a control voltage of the VCO 6. A signal which is proportional to the phase difference detected by the phase comparator 3 is output from the LPF 15.

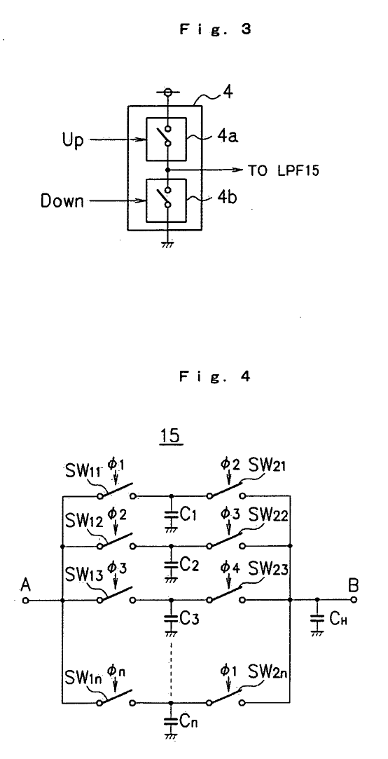

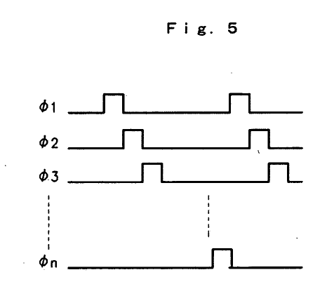

FIG. 4 is a diagram showing an example of a structure of the LPF 15 according to the present embodiment. As shown in FIG. 4, the LPF 15 according to the present embodiment includes a plurality of capacitors C₁ to Cₙ connected in parallel between an input terminal A and an output terminal B and a plurality of switches SW₁₁ to SW₁ₙ and SW₂₁ to SW₂ₙ for carrying out switching to perform a charging or discharging operation of the capacitors C₁ to Cₙ as a pipeline processing (which will be described below in detail).

Some of the capacitors C₁ to Cₙ and the switches SW₁₁ to SW₁ₙ and SW₂₁ to SW₂ₙ which have the same subscripts (1 to n) of the designations constitute a single path of a parallel circuit. For example, a single path is constituted by the capacitor C₁ and the switches SW₁₁ and SW₂₁ connected therebefore and thereafter. Similarly, another path is constituted by the capacitor C₂ and the switches SW₁₂ and SW₂₂ connected therebefore and thereafter. n paths are connected in parallel so that the parallel circuit is constituted.

Thus, the LPF 15 according to the present embodiment further includes a capacitor C_{H} on an output side of the parallel circuit including the capacitors C₁ to Cₙ and the switches SW₁₁ to SW₁ₙ and SW₂₁ to SW₂ₙ (between an output end of the parallel circuit and the ground). The capacitor C_{H} serves to hold electric charge's stored in the capacitors C₁ to Cₙ and output sequentially. For this reason, the capacitor C_{H} to be used has a greater capacitance value than capacitance values of the capacitors C₁ to Cₙ constituting the parallel circuit.

The VCO 6 in FIG. 2 is oscillated at a frequency which is proportional to a voltage of the signal output from the LPF 15, and generates a local oscillating signal and outputs the local oscillating signal to an outside of the frequency synthesizer and the variable frequency divider 7. The variable frequency divider 7 divides an output frequency of the VCO 4 at a specified dividing ratio and outputs the result as a comparison signal to the phase comparator 3. The frequency synthesizer thus constituted is operated in such a manner that a frequency of the comparison signal gradually approximates to that of the reference signal through a negative feedback loop even if the frequency of the comparison signal is higher or lower than that of the reference signal. Consequently, the oscillating frequency of the VCO 6 is locked into a constant frequency.

The frequency divider 11 divides a frequency of the reference signal output from the reference frequency divider 2 at a fixed dividing ratio. The clock generator 12 generates clock signals φ₁ to φₙ from the signal subjected to the frequency-division through the frequency divider 11. A clock generating circuit according to the present invention is constituted by the frequency divider 11 and the clock generator 12. The respective switches SW₁₁ to SW₁ₙ and SW₂₁ to SW₂ₙ in the LPF 15 are controlled to be switched based on the clock signals φ₁ to φₙ generated by the clock generator 12.

FIG. 5 is a diagram showing an example of the clock signals φ₁ to φₙ generated by the clock generator 12. As shown in FIG. 5, the clock generator 12 sequentially generates the clock signals φ₁ to φₙ without a mutual overlap in such a manner that one of the clock signals falls and the next clock then rises immediately. Thereafter, the generated clock signals φ₁ to φₙ are sequentially supplied to the respective switches SW₁₁ to SW₁ₙ and SW₂₁ to SW₂ₙ in the LPF 15.

At this time, the clock generator 12 supplies clock signals φᵢ and φᵢ₊₁ (n+1=1 is set with i=n) which is shifted in order by one to two switches SW₁ᵢ and SW₂ᵢ (i=1 to n) constituting a single path. More specifically, the clock signal φᵢ is supplied to the switch SW₁ᵢ connected before the capacitor C₁, and furthermore, the clock signal φᵢ₊₁ lagged by one is supplied to the switch SW₂ᵢ connected after the capacitor Cᵢ. In consideration of the paths, when the clock signals φᵢ and φᵢ₊₁ are supplied to the switches SW₁ᵢ and SW₂ᵢ of an i-th path, the clock signals φᵢ₊₁ and φᵢ₊₂ lagged by one are supplied to switches SW₁ᵢ₊₁ and SW₂ᵢ₊₁ of a next path.

Description will be given to an operation of the LPF 15 thus constituted. For example, an electric charge is supplied to the capacitor Cᵢ while the switch SW₁ᵢ connected before the capacitor Cᵢ in the i-th path is turned ON in response to the clock signal φᵢ. When the clock signal φᵢ falls so that the switch SW₁ᵢ is turned OFF, the switch SW₂ᵢ connected after the capacitor Cᵢ is immediately turned ON in response to the clock signal φᵢ₊₁ so that the electric charge stored in the capacitor Cᵢ in the ON state of the switch SW₁ᵢ is supplied to the capacitor C₁ᵢ connected to the output side of the parallel circuit.

The switch SW₁ᵢ₊₁ connected before the capacitor Cᵢ₊₁ in an (i+1)th path is simultaneously turned ON in response to the clock signal φᵢ₊₁ while the switch SW₂ᵢ connected after the capacitor Cᵢ in the i-th path is turned ON in response to the same clock signal φᵢ₊₁. Consequently, the electric charge is supplied to the capacitor Cᵢ₊₁ in the (i+1)th path while the electric charge stored in the capacitor Cᵢ in the i-th path is supplied to the capacitor C_{H}.

When the clock signal φᵢ₊₁ falls so that the switch SW₁ᵢ₊₁ is turned OFF, the switch SW₂ᵢ₊₁ connected after the capacitor Cᵢ₊₁ is immediately turned ON in response to the clock signal φᵢ₊₂ so that the electric charge stored in the capacitor Cᵢ₊₁ in the ON state of the switch SW₁ᵢ₊₁ is supplied to the capacitor C_{H}. At this time, the electric charge is simultaneously stored in a capacitor Cᵢ₊₂ in an (i+2)th path.

Thus, the electric charges are sequentially stored in the respective capacitors C₁ to Cₙ, and the electric charges stored respectively are sequentially supplied to the capacitor C_{H}. The capacitor C_{H} sequentially stores the electric charges supplied from the respective capacitors C₁ to Cₙ. As described above, the error signal having a pulse width corresponding to the phase difference between the reference signal and the comparison signal is supplied from the phase comparator 3 to the charge pump circuit 4. Therefore, the electric charges are supplied to the capacitor C_{H} corresponding to the pulse width of the error signal or the electric charges of the capacitor C_{H} are discharged corresponding to the pulse width of the error signal.

Description will be given to the capacitance value of the capacitor C_{H}. As described above, the charging and discharging operations of the capacitors C₁ to Cₙ are sequentially carried out as the pipeline processing. As a result, the electric charges supplied from the respective capacitors C₁ to Cₙ are successively stored in the capacitor C_{H} provided on the output side of the capacitors C₁ to Cₙ. Even if the capacitance value of the capacitor C_{H} is comparatively decreased so that the time constant is reduced, accordingly, the next electric charge is stored before the electric charge is lost due to a leakage current of the capacitor C_{H}. Consequently, the capacitance value of the capacitor C_{H} can be set to be smaller than that of a capacitor required in the conventional LPF 5.

For example, as the capacitor C_{H} which generates a very small leakage current, it is possible to use a PIP (polypropylene-insulator-polypropylene) capacitor, an MIM (metal-insulator-metal) capacitor, or an MOS (Metal Oxide Semiconductor) gate capacity, or the like.

As described above in detail, in the present embodiment, the LPF 15 is constituted by the capacitors C₁ to Cₙ connected in parallel, the switches SW₁₁ to SW₁ₙ and SW₂₁ to SW₂ₙ for carrying out switching to perform the charging or discharging operation of the capacitors C₁ to Cₙ as the pipeline processing, and the capacitor C_{H} connected to the output side of the parallel circuit including the capacitors C₁ to Cₙ and the switches SW₁₁ to SW₁ₙ and SW₂₁ to SW₂ₙ.

By the structure, the charging or discharging operation is carried out on the pipeline basis for the respective capacitors C₁ to Cₙ which are connected in parallel. As a result, the electric charges stored sequentially in the capacitors C₁ to Cₙ are obtained as an output of the parallel circuit and are sequentially stored in the capacitor C_{H}. Consequently, it is possible to implement a single capacitor having a great time constant as the whole circuit even if the time constants of the respective capacitors are reduced with a decrease in the capacitance values of the capacitors C₁ to Cₙ and C_{H}. Accordingly, it is possible to easily carry out an integration with the decrease in the capacitance values of the capacitors C₁ to Cₙ and C_{H} and to improve a C/N characteristic and a spurious characteristic irrespective of a synchronizing state of the frequency synthesizer.

Although FIG. 4 illustrates the structure for carrying out, as the pipeline processing, the charging or discharging operation of the capacitors C₁ to Cₙ connected in parallel in the embodiment described above, the present invention is not restricted thereto. It is also possible to employ any structure which can carry out the charging or discharging operation on the pipeline basis.

In addition, the embodiment is only illustrative for a concreteness to carry out the present invention and the technical range of the present invention should not be construed to be restrictive. In other words, the present invention can be carried out in various forms without departing from the spirit or main features thereof.

### INDUSTRIAL APPLICABILITY

The present invention is useful for a frequency synthesizer (for example, a PLL circuit) including a charge pump circuit and a loop filter.

This application is based on Japanese Patent Application No. 2006-209426 filed on Aug. 1, 2006, the contents of which are incorporated hereinto by reference.

What is claimed is:

1. A frequency synthesizer comprising:
a reference generator for generating a reference signal having a reference frequency;
a phase comparator for detecting a phase difference between the reference signal output from the reference generator and a comparison signal output from a variable frequency divider and outputting an error signal corresponding to a result of the detection;
a charge pump circuit for carrying out a charging or discharging operation of a capacitor constituting a loop filter based on the error signal output from the phase comparator;
the loop filter for removing an AC component from the error signal output from the phase comparator and passing through the charge pump circuit;
a voltage controlled oscillator for carrying out an oscillation at a frequency which is proportional to a voltage of a signal output from the loop filter, generating a local oscillating signal and outputting the local oscillating signal to the variable frequency divider; and
the variable frequency divider for dividing an output frequency of the voltage controlled oscillator at a specified dividing ratio and outputting the result as the comparison signal to the phase comparator,
wherein the loop filter includes a plurality of capacitors connected in parallel, a switch for carrying out switching to perform a charging or discharging operation of the capacitors as a pipeline processing, and a capacitor connected between an output of a parallel circuit having the capacitors and a ground.

2. The frequency synthesizer according to claim 1, further comprising a clock generating circuit for frequency-dividing the reference signal having the reference frequency which is output from the reference generator, thereby generating a clock signal,
the switch of the loop filter being controlled to carry out switching based on the clock signal generated by the clock generating circuit.

3. A loop filter comprising:
a plurality of capacitors connected in parallel;
a switch for carrying out switching to perform a charging or discharging operation of the capacitors as a pipeline processing; and
a capacitor connected between an output of a parallel circuit including the capacitors and a ground.
